(19) United States
(12) Patent Application Publication
(10) Pub. No.: US 2025/0372342 A1
(43) Pub. Date: Dec. 4, 2025

(54) CHARGED PARTICLE BEAM WRITING METHOD AND CHARGED PARTICLE BEAM WRITING APPARATUS

(71) Applicant: NuFlare Technology, Inc., Yokohama-shi (JP)

(72) Inventors: Issei AIBARA, Yokohama-shi (JP); Jumpei YASUDA, Kamakura-shi (JP)

(73) Assignee: NuFlare Technology, Inc., Yokohama-shi (JP)

(21) Appl. No.: 19/216,860

(22) Filed: May 23, 2025

(30) Foreign Application Priority Data
Jun. 4, 2024 (JP) 2024-090875

(51) Int. Cl. H01J 37/244; H01J 37/147; H01J 37/153; H01J 37/317

(52) U.S. Cl. CPC H01J 37/244; H01J 37/1472; H01J 37/153; H01J 37/3174; H01J 2237/1536; H01J 2237/21; H01J 2237/24465; H01J 2237/24578

(57) ABSTRACT

In one embodiment, a charged particle beam writing method includes deflecting a charged particle beam at a position with a deflection offset added so that a zero-state of any deflection voltage is excluded from a range of deflection voltages applied to a plurality of electrodes of an electrostatic positioning deflector, irradiating a substrate with the charged particle beam, and changing a quadrant of the deflection offset at a predetermined timing or based on a drift amount of the charged particle beam, the quadrant being relative to an origin of deflection voltage at which all deflection voltages are zero.

### CROSS REFERENCE TO RELATED APPLICATION

This application is based upon and claims benefit of priority from the Japanese Patent Application No. 2024-90875, filed on Jun. 4, 2024, the entire contents of which are incorporated herein by reference.

### FIELD

The present invention relates to a charged particle beam writing method and a charged particle beam writing apparatus.

### BACKGROUND

As LSI circuits are increasing in density, the required linewidths of circuits included in semiconductor devices become finer year by year. To form a desired circuit pattern on a semiconductor device, a method is employed in which a high-precision original pattern (i.e., a mask, or also particularly called reticle, which is used in a stepper or a scanner) formed on quartz is transferred to a wafer in a reduced manner by using a reduced-projection exposure apparatus. The high-precision original pattern is written by using an electron-beam writing apparatus, in which a so-called electron-beam lithography technique is employed.

As an example of electron beam writing apparatus, a multi-electron beam writing apparatus using a multi-beam is known. Compared to a writing apparatus using a single electron beam, the multi-electron beam writing apparatus can irradiate many beams at one time, thus the throughput can be significantly improved.

In the multi-electron beam writing apparatus, the beam of each shot is focused on the surface of a substrate as a writing target by an objective lens, and focus correction (dynamic focus) is performed dynamically using an electrostatic lens during writing to adjust for irregularities on the substrate surface. When the electrostatic lens is operated in a negative voltage range, secondary electrons generated due to electron beam writing return to the substrate surface, thereby causing the resist to be charged, and preventing improvement of the dimensional accuracy of a writing pattern.

To reduce the effect of the return of secondary electrons, it is preferable that the electrostatic lens be operated in a positive voltage range with respect to the substrate surface, and the secondary electrons be guided upward from the substrate surface.

However, when the electrostatic lens is operated in a positive voltage range, the secondary electrons from the substrate surface pass through the electrostatic lens, then are abruptly decelerated to stay in the beam trajectory densely, or charge non-conductive dirt (contamination) on the inner surface of the electrodes of the deflector, thereby causing the electric field near the electron beam to change, which creates a problem in that the trajectory of the electron beam is displaced, and the beam positional accuracy is deteriorated.

### BRIEF DESCRIPTION OF THE DRAWINGS

FIG. 1 is a schematic view of a multi-charged particle beam writing apparatus according to an embodiment of the present invention.

FIG. 2 is a schematic view of a shaping aperture array substrate.

FIG. 3 is a sectional view of a second objective lens.

FIGS. 4A and 4B are views for explaining a trajectory of secondary electron according to a comparative example.

FIG. 5 is a view for explaining a deflectable range and a writing deflection region.

FIGS. 6A and 6B are views for explaining a trajectory of secondary electron.

FIGS. 7A to 7D are views for explaining the positions of writing deflection region where the polarity of deflection voltage is constant.

FIG. 8 is a view illustrating a configuration example of a positioning deflector.

FIGS. 9A and 9B are views illustrating a configuration example of a positioning deflector.

FIGS. 10A to 10C are views for explaining the positions of writing deflection region where the polarity of deflection voltage is constant.

FIGS. 11A and 11B are views for explaining the positions of writing deflection region where the polarity of deflection voltage is constant.

FIG. 12 is a view illustrating a modification example of an offsettable region in which a writing deflection region is located.

FIG. 13 is a flowchart for explaining a writing method according to the embodiment.

FIG. 14 is a view for explaining the configuration of a positioning deflector and voltages applied to electrodes.

### DETAILED DESCRIPTION

In one embodiment, a charged particle beam writing method includes deflecting a charged particle beam at a position with a deflection offset added so that a zero-state of any deflection voltage is excluded from a range of deflection voltages applied to a plurality of electrodes of an electrostatic positioning deflector, irradiating a substrate with the charged particle beam, and changing a quadrant of the deflection offset at a predetermined timing or based on a drift amount of the charged particle beam, the quadrant being relative to an origin of deflection voltage at which all deflection voltages are zero.

Hereinafter, an embodiment of the present invention will be described based on the drawings. In the present embodiment, a configuration using an electron beam as an example of a charged particle beam will be described. The charged particle beam is not limited to the electron beam. For example, the charged particle beam may be an ion beam.

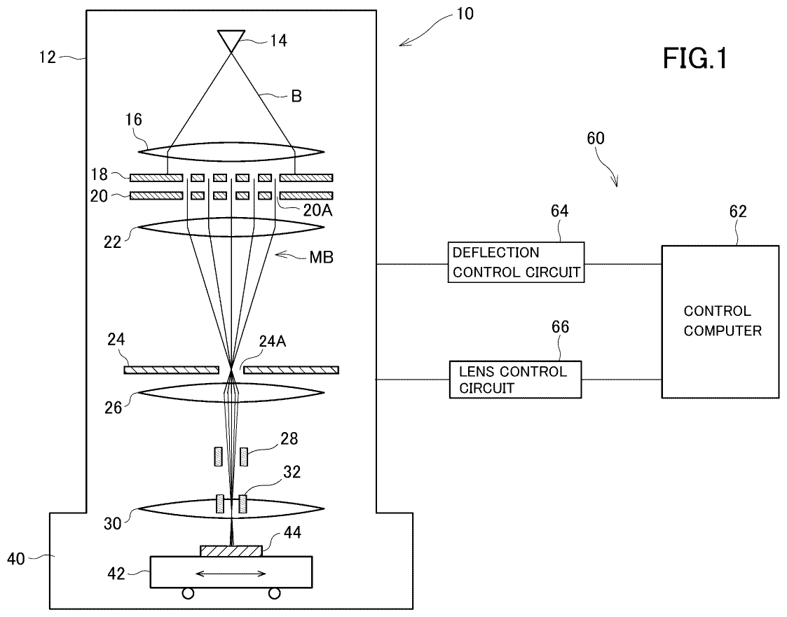

The writing apparatus illustrated in FIG. 1 includes a writer 10 that writes a desired pattern by irradiating an object such as a mask or a wafer with an electron beam, and a controller 60 that controls the operation of the writer 10. The writer 10 includes an electron optical column 12 and a writing chamber 40. In this embodiment, the configuration using a multi-beam writing apparatus as an example of a writing apparatus will be described.

In the electron optical column 12, an electron source 14, an illumination lens 16, a shaping aperture array substrate 18, a blanking aperture array substrate 20, a projection lens 22, a stopping aperture (limiting aperture member) 24, a first objective lens 26, a positioning deflector 28, a second objective lens 30, and a focus correction lens 32 are disposed. In the writing chamber 40, an XY stage 42 is disposed. On the XY stage 42, a mask blank is placed which is a substrate 44 as a writing target.

The substrate 44 may refer to e.g., a wafer, and an exposure mask to which a pattern is transferred using a reduction projection exposure device or an extreme ultraviolet ray exposure device, such as a stepper or a scanner with an excimer laser as a light source. In addition, the substrate 44 may refer to a mask in which a pattern is already formed. For example, a Levenson mask needs two times of writing, thus a second pattern may be written on the mask on which writing has been performed once.

As illustrated in FIG. 2, in the shaping aperture array substrate 18, openings (first openings) 18A in m vertical rows×n horizontal rows (m, n≥2) are formed with a predetermined arrangement pitch. The openings 18A are formed in e.g., rectangular shapes having the same dimensions. The shape of the openings 18A may be circular. Part of an electron beam B passes through a corresponding one of these multiple openings 18A, thereby forming a multi-beam MB.

The blanking aperture array substrate 20 is provided below the shaping aperture array substrate 18, and passage holes 20A (second openings) corresponding to the openings 18A of the shaping aperture array substrate 18 are formed. A blanker (not illustrated) consisting of a set of two paired electrodes is disposed in each passage hole 20A. One electrode of the blanker is fixed to the ground electric potential, and the other electrode is switched to an electric potential different from the ground electric potential. Electron beams passing through respective passage holes 20A are each independently deflected by a voltage applied to a corresponding one of blankers. In this manner, multiple blankers perform blanking deflection on corresponding beams in the multi-beam MB which has passed through the multiple openings 18A of the shaping aperture array substrate 18.

The stopping aperture 24 blocks each beam which has been deflected by a blanker. Each beam not deflected by a blanker passes through an opening 24A (third opening) formed in the center of the stopping aperture 24. To reduce beam leakage at the time of individual blanking by the blanking aperture array substrate 20, the stopping aperture 24 is disposed on the imaging surface of a crossover (light source image) where the spread of beam is small.

The controller 60 includes a control computer 62, a deflection control circuit 64, and a lens control circuit 66. The deflection control circuit 64 controls the voltage applied to each blanker provided in the blanking aperture array substrate 20, and each electrode of the positioning deflector 28. The lens control circuit 66 controls the voltage applied to the illumination lens 16, the projection lens 22, the first objective lens 26, the second objective lens 30 and the focus correction lens 32. For example, the lens control circuit 66 controls the voltage applied to the focus correction lens 32, and performs focus correction (dynamic focus) based on the surface height of the substrate 44 detected by a Z sensor (not illustrated).

The electron beam B emitted from the electron source 14 (emitter) illuminates the entire shaping aperture array substrate 18 substantially perpendicularly via the illumination lens 16. The electron beam B passes through the multiple openings 18A of the shaping aperture array substrate 18, thereby forming the multi-beam MB consisting of multiple electron beams. The multi-beam MB passes through corresponding blankers of the blanking aperture array substrate 20.

The multi-beam MB passing through the blanking aperture array substrate 20 is reduced by the projection lens 22, and travels to the opening 24A formed in the center of the stopping aperture 24. Here, each electron beam deflected by a blanker of the blanking aperture array substrate 20 is displaced from the opening 24A of the stopping aperture 24, and is blocked by the stopping aperture 24. In contrast, each electron beam not deflected by a blanker passes through the opening 24A of the stopping aperture 24. Blanking control is performed by ON/OFF of each blanker so that ON/OFF of the beam is controlled.

In this manner, the stopping aperture 24 blocks each beam which has been deflected to achieve a beam OFF state by a blanker of the blanking aperture array substrate 20.

The multi-beam MB which has passed through the stopping aperture 24 is focused by the first objective lens 26, the second objective lens 30 and the focus correction lens 32 to form a pattern image with a desired reduction ratio, and is emitted onto the substrate 44.

The positioning deflector 28 disposed between the first objective lens 26 and the second objective lens 30 deflects and emits the multi-beam MB to a desired position of the substrate 44 placed on the XY stage 42 which moves continuously. The positioning deflector 28 has multiple electrodes, and a quadrupole deflector having four electrodes or an octupole deflector having eight electrodes may be used as the positioning deflector 28. The beam deflection position (beam irradiation position in the substrate 44) by changing the voltage applied to each electrode of the positioning deflector 28.

The dimensions of the spot on the substrate 44 irradiated with the multi-beam MB are large e.g., approximately 100 micrometer square, thus even if the dimensions of the region (writing deflection region) to be deflected by the positioning deflector 28 are less than the dimensions of the beam array of the multi-beam MB, no problem occurs regarding writing throughput. For example, it is sufficient that the dimensions of the writing deflection region be from several micrometer square to 10 micrometer square.

The focus correction lens 32 is disposed downstream of the positioning deflector 28 in the traveling direction of the multi-beam MB.

Although an electromagnetic lens (magnetic field lens) is used as the illumination lens 16, the projection lens 22, the first objective lens 26 and the second objective lens 30, an electrostatic lens may be used for those lenses in part or all. The focus correction lens 32 performs dynamic focus adjustment for height variation of the surface of the substrate 44, and an electrostatic lens is used as the focus correction lens 32, but an electromagnetic lens (including a coil that generates an axis-symmetric magnetic field) may be used. Alternatively, the focus correction lens 32 may be comprised of a multistage lens system in which applied voltages and exciting currents change in a coordinated manner while maintaining a certain relationship. Alternatively, the second objective lens 30 may have the function of the focus correction lens 32 as well, or focus adjustment may be made by operating the second objective lens 30 and the focus correction lens 32 in a coordinated manner while maintaining a certain relationship.

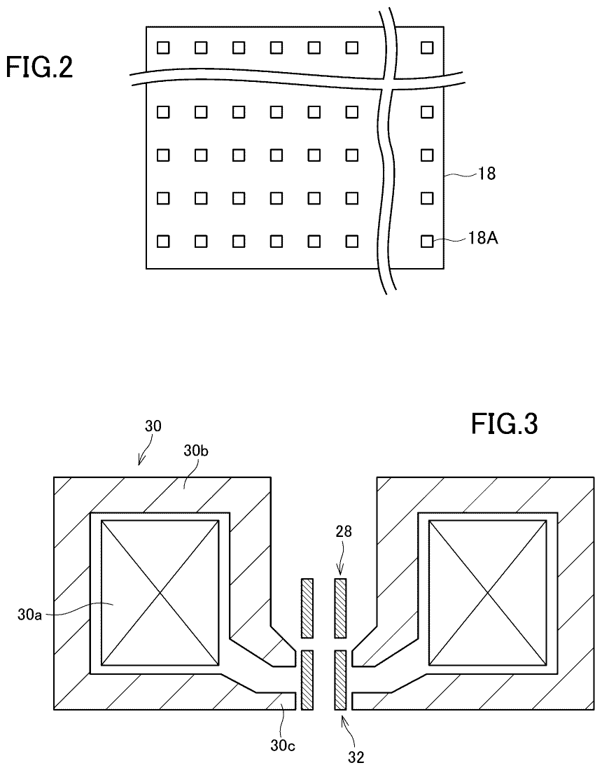

The second objective lens 30 is an electromagnetic lens, and includes a coil 30a, and a yoke 30b that stores the coil 30a as illustrated in FIG. 3. The yoke 30b is made of a material with a high permeability, such as iron, and is provided with a notch (pole piece 30c) in part.

The magnetic field lines produced by passing a current through the coil 30a leak into space through the pole piece 30c, and a magnetic field is generated.

The focus correction lens 32 is disposed according to e.g., the inside of the second objective lens 30, for example, the height of the pole piece 30c. The focus correction lens 32 is an electrostatic lens, and has a ring-shaped electrode. A positive voltage with respect to the substrate surface is applied to this electrode, and the focus correction lens 32 is operated in a positive voltage range with respect to the substrate surface.

When the substrate 44 is irradiated with the multi-beam MB (primary beam), secondary electrons are emitted from the substrate surface. Due to the operation of the focus correction lens 32 in a positive voltage range, the secondary electrons are guided upward from the substrate surface to travel upward within the electron optical column 12. It is possible to prevent the secondary electrons from returning to the substrate surface, and to reduce position variation due to charging of the resist.

In the writing process, the resist on the surface of the substrate 44 is vaporized by beam irradiation, and contamination (dirt) may adhere to the surface of multiple electrodes of the positioning deflector 28. The secondary electrons traveling upward within the electron optical column 12 reach the contamination on the electrode surface of the positioning deflector 28, and are charged, which may change the trajectory of the multi-beam MB.

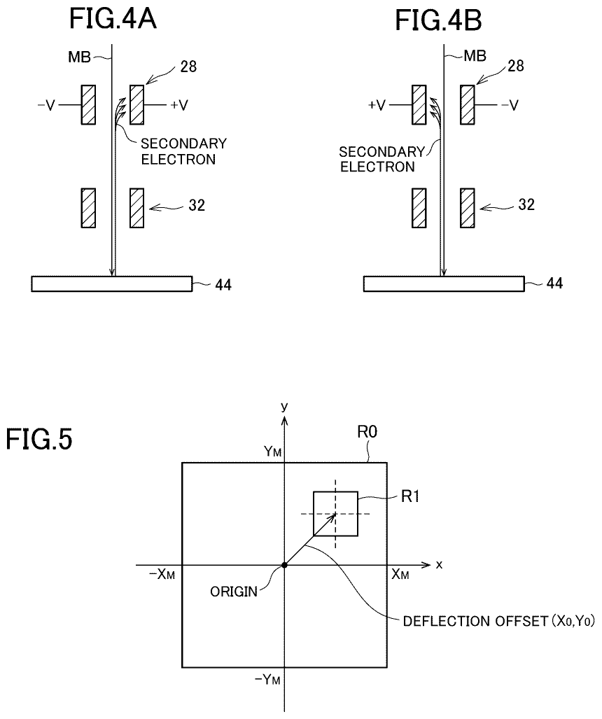

In a conventional writing apparatus, in an operation to change the beam deflection position (beam irradiation position in the substrate 44), as illustrated in FIG. 4A, FIG. 4B, the polarity of deflection voltage applied to each electrode of the positioning deflector 28 changes frequently. When the polarity of deflection voltage changes, the intensity and direction of the electric field in the positioning deflector 28 changes significantly, thus the arrival position of secondary electron, in other words, the charge position significantly changes across the electrodes. Since the charge position significantly changes, a significant change occurs in the electric field in the vicinity of the beam, and as a result, a significant beam irradiation position variation (drift) occurs.

Thus, in this embodiment, a writing operation is performed with an offset (deflection offset) added to the deflection position of the positioning deflector 28, in other words, with a shift in the deflection position, thereby removing secondary electrons from the vicinity of the beam center, and causing the secondary electrons to move in a substantially constant lateral direction. Consequently, the secondary electrons reach a restricted region on the deflector surface or the like.

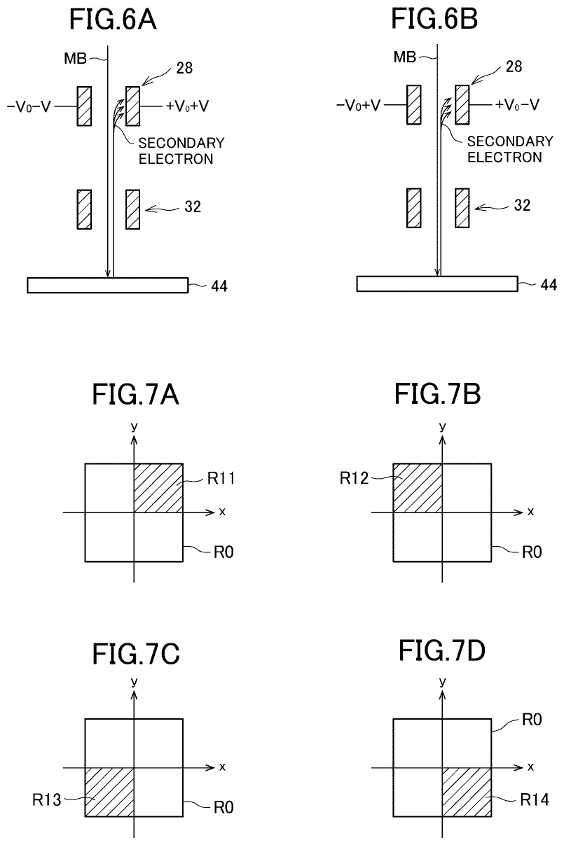

For example, as illustrated in FIG. 5, a writing deflection region R1 is shifted within a deflectable range R0 so that the origin of deflection voltage, in other words, 0-state of the deflection voltage (either one deflection voltage is 0) of any electrode of the positioning deflector 28 is excluded from a writing deflection region R1. Here, the deflectable range R0 is a range into which a beam can be deflected by the positioning deflector 28 with the maximum output of a deflection amplifier included in the deflection control circuit 64. The writing deflection region R1 is a deflection region required for the writing process. As illustrated in FIG. 6A, FIG. 6B, change in the arrival position of secondary electron in other words, change in the charge position for change in the deflection position is reduced by excluding the origin of deflection voltage from the writing deflection region R1, thus the beam irradiation position variation (drift) is reduced.

In addition, it is more effective to set the deflection offset so that the polarity of the deflection voltage of each electrode (individual electrode) of the positioning deflector 28 is constant and unchanged. In order to set the polarity of the deflection voltage of each electrode to be constant in a quadrupole deflector, it is sufficient that the writing deflection region R1 be included in one of the offsettable regions R11 to R14 illustrated in FIGS. 7A to 7D. Thus, the region of the deflection electrode, hit by secondary electron is further restricted, therefore, the range of location where charging occurs is also further restricted. As a result, change in the intensity and direction of the electric field in the positioning deflector 28 is reduced, and the beam irradiation position variation (drift) is reduced, thereby improving the beam position accuracy.

Note that when “the deflection offset is set so that the polarity of the deflection voltage of each electrode becomes constant”, “0-state of the deflection voltage of any electrode is excluded” is satisfied automatically (inevitably). Therefore, “the polarity becomes constant” is a condition that further restricts “0-state of the deflection voltage of any electrode is excluded”.

Note that a condition on the voltage applied to the deflector contributes to drift reduction more directly. Only as a result, the beam deflection position and deflection region on the substrate surface are shifted, and it cannot be stated that the beam deflection position and deflection region themselves on the substrate necessarily contribute to drift reduction directly.

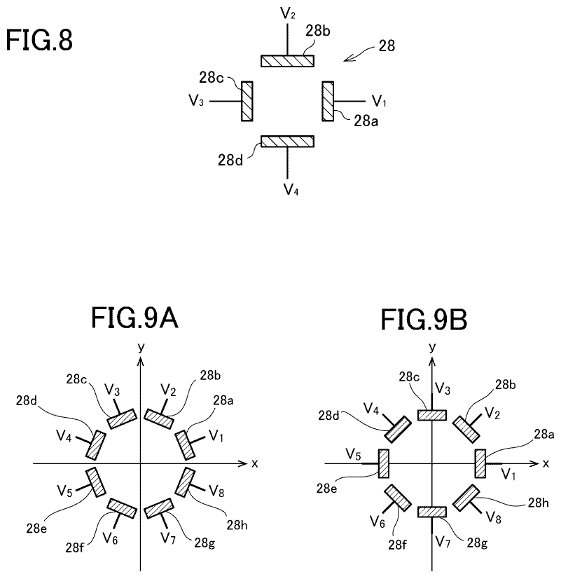

FIG. 8 illustrates an example of the configuration of the positioning deflector 28. In the example illustrated in FIG. 8, the positioning deflector 28 is an electrostatic quadrupole deflector having four electrodes 28a to 28d. Let (X₀, Y₀) be the deflection offset, (X, Y) be the amount of deflection for pattern writing based on the pattern position of writing data, and k be the deflection sensitivity coefficient, then the deflection voltages V₁ to V₄ applied to the electrode 28a to 28d are as follows.

$${V}_{1} = k ( {X}_{0} + X ) \\ {V}_{2} = k ( {Y}_{0} + Y ) \\ {V}_{3} = k ( - {X}_{0} - X ) \\ {V}_{4} = k ( - {Y}_{0} - Y )$$

The case will be discussed where the deflectable range in the x direction is from −X_{M} to X_{M}, the deflectable range in the y direction is from −Y_{M} to Y_{M}, the writing deflection region in the x direction is from −X_{W} to X_{W}, and the writing deflection region in the y direction is from −Y_{W} to Y_{W}. As illustrated in FIG. 5, it is sufficient that the deflection offset (X₀, Y₀) satisfy the following conditional expressions in order to not include the origin of deflection voltage in the writing deflection region R1, and generate a constant polarity of the deflection voltage of each electrode of the positioning deflector 28.

$${X}_{W} < \vert {X}_{0} \vert ≦ {X}_{M} - Xw \\ {Y}_{W} < \vert {Y}_{0} \vert ≦ {Y}_{M} - Yw$$

The deflection offset (X₀, Y₀) satisfying the above conditional expressions is determined in advance, and stored in a memory (not illustrated) of the controller 60.

In a writing process, the control computer 62 reads writing data from a storage device, and performs a multistage data conversion process to generate shot data specific to the apparatus. In the shot data, the irradiation amount, irradiation position coordinates and the like of each shot are defined. The irradiation position coordinates are calculated using the above-mentioned deflection offset (X₀, Y₀) as the origin of deflection.

The control computer 62 outputs the irradiation amount of each shot to the deflection control circuit 64 based on the shot data. The deflection control circuit 64 determines the irradiation time t by dividing the input irradiation amount by a current density. When performing a corresponding shot, the deflection control circuit 64 applies a deflection voltage to a corresponding blanker of the blanking aperture array substrate 20 so that the blanker is beam ON by the irradiation time t.

The deflection control circuit 64 determines the deflection amount (X, Y) for writing so that the irradiation position indicated by the shot data is irradiated with the beam, adds or subtracts the deflection offset (X₀, Y₀) to or from the deflection amount, and multiplies the resulting amount by the deflection sensitivity coefficient k to obtain the above-mentioned deflection voltages V₁ to V₄ which are applied to the respective electrodes 28a to 28d of the positioning deflector 28. Note that when the deflection amount for writing is determined, positional information of the XY stage 42 is obtained from a position measuring instrument (not illustrated) such as a laser length measuring device, and utilized.

In this manner, the polarity of the deflection voltage of each deflection electrode of the positioning deflector 28 is made to be constant so that secondary electrons are guided to a restricted region of the positioning deflector 28, thus change in charging of the deflector is reduced, and the beam can be stabilized.

The positioning deflector 28 may use an octupole deflector having eight electrodes 28a to 28h as illustrated in FIG. 9A, FIG. 9B. The deflectors illustrated in FIG. 9A, FIG. 9B have installation angles which differ by 22.5 degrees, and in the present specification, arrangement in which each deflection coordinate axis passes through the center of the space between deflection electrodes as in FIG. 9A is referred to as 22.5-degree rotation arrangement, and arrangement in which each deflection coordinate axis passes through the center of a deflection electrode as in FIG. 9B is referred to as 0-degree rotation arrangement.

In the 22.5-degree rotation arrangement illustrated in FIG. 9A, the deflection voltages V₁ to V₈ applied to the electrodes 28a to 28h are expressed as below using the deflection offset (X₀, Y₀), the deflection amount for writing (X, Y), and the deflection sensitivity coefficient k.

$${V}_{1} = k \{ ( {X}_{0} + X ) + a ( {Y}_{0} + Y ) \} \\ {V}_{2} = k \{ ( {Y}_{0} + Y ) + a ( {X}_{0} + X ) \} \\ {V}_{3} = k \{ ( {Y}_{0} + Y ) - a ( {X}_{0} + X ) \} \\ {V}_{4} = k \{ - ( {X}_{0} + X ) + a ( {Y}_{0} + Y ) \} \\ {V}_{5} = k \{ ( - {X}_{0} + X ) - a ( {Y}_{0} + Y ) \} \\ {V}_{6} = k \{ - ( {Y}_{0} + Y ) - a ( {X}_{0} + X ) \} \\ {V}_{7} = k \{ - ( {Y}_{0} + Y ) + a ( {X}_{0} + X ) \} \\ {V}_{8} = k \{ ( {X}_{0} + X ) - a ( {Y}_{0} + Y ) \} \\ a = √ 2 - 1 \approx 0.414$$

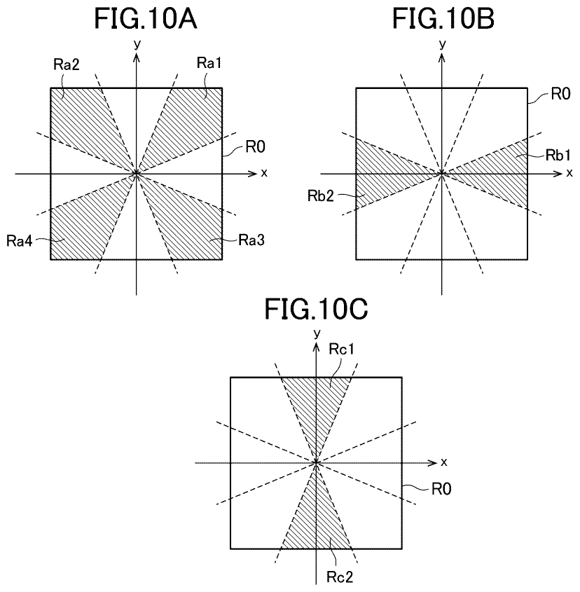

In the 22.5-degree rotation arrangement, in order to make the polarity of the deflection voltage of each electrode of the positioning deflector 28 constant, it is sufficient that the writing deflection region be included in one of the following regions: the offsettable regions Ra (Ra1 to Ra4), that is, the region between 22.5 degrees and 67.5 degrees, and the regions obtained by rotating the region every 90 degrees as illustrated in FIG. 10A, the offsettable regions Rb (Rb1, Rb2), that is, the region between-22.5 degrees and 22.5 degrees, and the region rotated 180 degrees as illustrated in FIG. 10B, and the offsettable regions Rc (Rc1, Rc2), that is, the region between 67.5 degrees and 112.5 degrees, and the region rotated 180 degrees as illustrated in FIG. 10C.

In order to include the writing deflection region in one of the offsettable regions Ra1 to Ra4, it is sufficient that the deflection offset (X₀, Y₀) satisfy the following conditional expressions.

$$\vert {Y}_{0} \vert + {Y}_{W} < ( √ 2 + 1 ) ( \vert {X}_{0} \vert - {X}_{W} ) \\ \vert {Y}_{0} \vert - {Y}_{W} > ( √ 2 - 1 ) ( \vert {X}_{0} \vert + {X}_{W} ) \\ \vert {X}_{0} \vert ≦ {X}_{M} - {X}_{W} \\ \vert {Y}_{0} \vert ≦ {Y}_{M} - {Y}_{W}$$

In order to include the writing deflection region in the offsettable region Rb1 or Rb2, it is sufficient that the deflection offset (X₀, Y₀) satisfy the following conditional expressions.

$$\vert {Y}_{0} \vert + {Y}_{W} < ( √ 2 - 1 ) ( \vert {X}_{0} \vert - {X}_{W} ) \\ \vert {Y}_{0} \vert - {Y}_{W} > - ( √ 2 - 1 ) ( \vert {X}_{0} \vert - {X}_{W} ) \\ \vert {X}_{0} \vert ≦ {X}_{M} - {X}_{W} \\ \vert {Y}_{0} \vert ≦ {Y}_{M} - {Y}_{W}$$

In order to include the writing deflection region in the offsettable region Rc1 or Rc2, it is sufficient that the deflection offset (X₀, Y₀) satisfy the following conditional expressions.

$$\vert {X}_{0} \vert + Xw < ( √ 2 - 1 ) ( \vert {Y}_{0} \vert - {Y}_{W} ) \\ \vert {X}_{0} \vert - Xw > - ( √ 2 - 1 ) ( \vert {Y}_{0} \vert - {Y}_{W} ) \\ \vert {X}_{0} \vert ≦ {X}_{M} - {X}_{W} \\ \vert {Y}_{0} \vert ≦ {Y}_{M} - {Y}_{W}$$

In the 0-degree rotation arrangement illustrated in FIG. 9B, the deflection voltages V₁ to V₈ applied to the electrodes 28a to 28h are expressed as below using the deflection offset (X₀, Y₀), the deflection amount for writing (X, Y), and the deflection sensitivity coefficient k′.

$${V}_{1} = {k}^{′} ( {X}_{0} + X ) \\ {V}_{2} = {k}^{′} b \{ ( {X}_{0} + X ) + ( {Y}_{0} + Y ) \} \\ {V}_{3} = {k}^{′} ( {Y}_{0} + Y ) \\ {V}_{4} = {k}^{′} b \{ - ( {X}_{0} + X ) + ( {Y}_{0} + Y ) \} \\ {V}_{5} = - {k}^{′} ( {X}_{0} + X ) \\ {V}_{6} = - {k}^{′} b \{ ( {X}_{0} + X ) + ( {Y}_{0} + Y ) \} \\ {V}_{7} = - {k}^{′} ( {Y}_{0} + Y ) \\ {V}_{8} = - {k}^{′} b \{ - ( {X}_{0} + X ) + ( {Y}_{0} + Y ) \} \\ b = 1 / √ 2 \approx 0.707$$

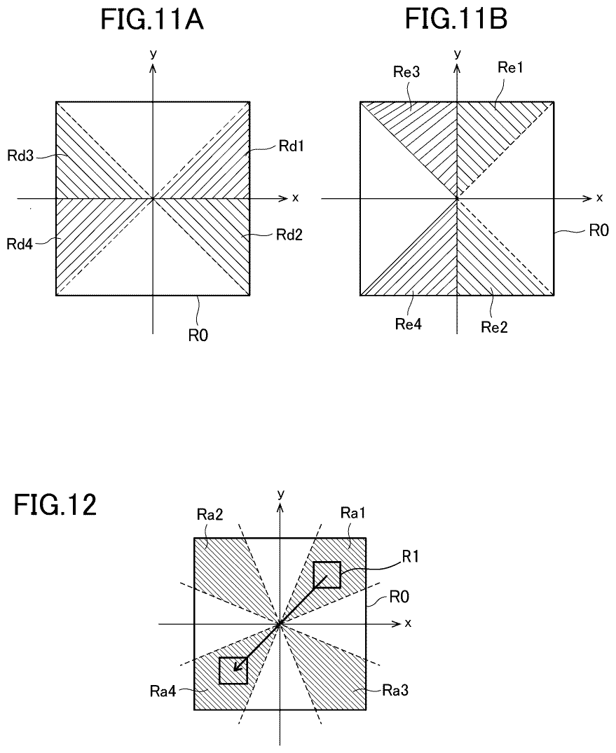

In the 0-degree rotation arrangement, in order to make the polarity of the deflection voltage of each electrode of the positioning deflector 28 constant, it is sufficient that the writing deflection region be included in one of the following regions: the offsettable regions Rd (Rd1 to Rd4), that is, the region between 0 degree and 45 degrees, and the regions symmetric to the region about the x-axis, the y-axis, and the origin as illustrated in FIG. 11A, and the offsettable regions Re (Re1 to Re4), that is, the region between 45 degree and 90 degrees, and the regions symmetric to the region about the x-axis, the y-axis, and the origin as illustrated in FIG. 11B.

In order to include the writing deflection region in the offsettable regions Rd1 to Rd4, it is sufficient that the deflection offset (X₀, Y₀) satisfy the following conditional expressions.

$$\vert {Y}_{0} \vert + {Y}_{W} < \vert {X}_{0} \vert - {X}_{W} \\ \vert {X}_{0} \vert ≦ {X}_{M} - {X}_{W} \\ \vert {Y}_{0} \vert ≦ {Y}_{M} - {Y}_{W} \\ \vert {Y}_{0} \vert > {Y}_{W}$$

In order to include the writing deflection region in the offsettable regions Re1 to Re4, it is sufficient that the deflection offset (X₀, Y₀) satisfy the following conditional expressions.

$$\vert {X}_{0} \vert + {X}_{W} < \vert {Y}_{0} \vert - {Y}_{W} \\ \vert {X}_{0} \vert ≦ {X}_{M} - {X}_{W} \\ \vert {Y}_{0} \vert ≦ {Y}_{M} - {Y}_{W} \\ \vert {X}_{0} \vert > {X}_{W}$$

From the viewpoint of drift reduction, it is effective to make the deflection offset constant during a writing operation. However, for example, when contamination is originally present in the direction of a deflection offset, if the deflection offset is always constant, the contamination significantly grows, which may cause the beam trajectory to change, and large drift may occur.

Thus, in this embodiment, drift is measured during a writing operation with a predetermined time interval, and when the drift amount is greater than or equal to a predetermined threshold value, the quadrant (and size) of a deflection offset are changed, and the offsettable region in which the writing deflection region is located is changed to a different offsettable region. For example, as illustrated in FIG. 12, the offsettable region in which the writing deflection region R1 is located is changed from the offsettable region Ra1 to the offsettable region Ra4. Consequently, growth of the contamination can be inhibited, and drift can be reduced.

Here, changing the quadrant of deflection offset refers to changing the central position of the writing deflection region to another quadrant (a position where the polarity in at least one of X, Y is changed) in a circumferential direction about the center at the origin (see FIG. 5) of deflection voltage. Also, changing the size of deflection offset refers to increasing/decreasing the distance between the central position of the writing deflection region and the origin of deflection voltage.

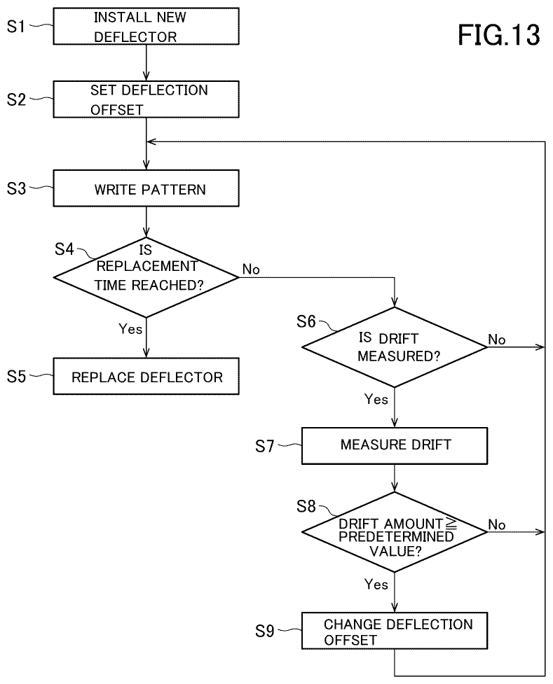

The writing method according to this embodiment will be described based on the flowchart illustrated in FIG. 13. A new positioning deflector 28 is installed in the writing apparatus, and a deflection offset is set (steps S1, S2). For example, as illustrated in FIG. 9A, an octupole deflector is arranged with 22.5-degree rotation, and the deflection offset is set so that the writing deflection region is included in the offsettable region Ra1 illustrated in FIG. 10A.

The substrate 44 is irradiated with a beam to write a pattern (step S3). The irradiation position coordinates are calculated using the deflection offset set in step S2 as the origin of deflection, the deflection offset is added or subtracted to or from the deflection amount for writing, and the deflection voltage is applied to each electrode of the positioning deflector 28.

The positioning deflector 28 is continuously used until usage time exceeds a predetermined value (step S4_No), when replacement time is reached after use for a predetermined time (step S4_Yes), the positioning deflector 28 is replaced (step S5).

While a writing process is being performed by continuously using the positioning deflector 28, the writing process is suspended at a predetermined timing, and drift is measured (step S6_Yes, step S7). The method for measuring drift is not limited, and a publicly known method may be used. For example, only a specific beam (or a beam group including multiple beams) in the multi-beam is set ON, a mark (not illustrated) on the XY stage 42 is scanned by the beam, and reflected electrons are detected by a detector (not illustrated). The control computer 62 calculates the beam position from the waveform of the amount of detected reflected electrons and the stage position, and determines the drift amount from the difference between the calculated beam position and an ideal value. Instead of a reflective mark, a transparent mark may be used, which is scanned to detect the beam which has passed through the opening of the transparent mark, and the beam position may be calculated from the waveform of the amount of detected reflected electrons and the stage position.

When the drift amount is less than a predetermined value (step S8_No), a pattern writing is continued without changing the deflection offset.

When the drift amount is greater than or equal to a predetermined value (step S8_Yes), contamination has probably grown in the quadrant of the current deflection offset significantly, thus the quadrant of deflection offset is changed, and the offsettable region in which the writing deflection region is located is changed to a different offsettable region (step S9). For example, as illustrated in FIG. 12, the offsettable region in which the writing deflection region R1 is located (included) is changed from the offsettable region Ra1 to the offsettable region Ra4. A deflection offset after the change is set, and the writing process is restarted (step S3).

In this manner, according to this embodiment, the focus correction lens 32 is operated in a positive voltage range with respect to the substrate surface, thus secondary electrons can be guided upward from the substrate surface, and stay of secondary electrons in space can be prevented. Also, a deflection offset is set and the writing deflection region is shifted so that the 0-state of the deflection voltage of any electrode of the positioning deflector 28 is excluded, and when the drift amount is increased, the quadrant (and size) of deflection offset are changed, and the offsettable region in which the writing deflection region is located is changed, thus variation in the beam position due to charging of deflector electrodes can be reduced, and the writing accuracy can be improved.

In step S9 of FIG. 13, a change destination (quadrant at a change destination) of the offsettable region in which the writing deflection region is located may be selected at random, or the drift amount is measured in each offsettable region and an optimal offsettable region in which the drift amount is minimum may be selected. For example, when the offsettable region in which the writing deflection region is located is changed from the offsettable region Ra1 to either one of other offsettable regions Ra2 to Ra4 in FIG. 10A, drift is measured with the writing deflection region located in each of the offsettable regions Ra2 to Ra4, and an offsettable region in which the drift amount is minimum is selected.

The drift amount in each offsettable region may be saved in a memory (not illustrated), and subsequently, when the deflection offset is changed, an offsettable region may be selected in ascending order of drift amount saved.

In the above embodiment, the quadrant of deflection offset is changed using the positioning deflector; however, the quadrant of deflection offset may be changed by a deflector different from the positioning deflector.

In the above embodiment, an example has been described in which the deflection offset is changed when a measured drift amount is greater than or equal to a predetermined value; however, the deflection offset may be changed when the writing time or the number of times of writing (the number of written substrates) reaches a predetermined value.

In the above embodiment, an example has been described in which the offsettable region in which the writing deflection region is located is changed by changing the deflection offset; however, the writing deflection region may be moved within the same offsettable region.

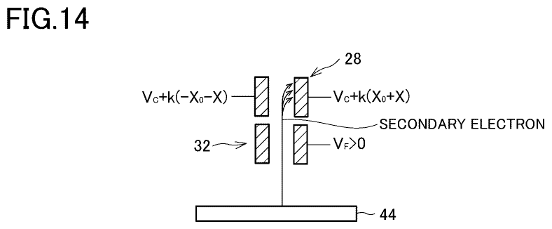

As illustrated in FIG. 14, a positive common voltage V_{C} with respect to the substrate surface may be added to the voltage applied to each electrode of the positioning deflector 28. The common voltage V_{C} is preferably higher than or equal to the upper limit value of a positive voltage VF applied to the focus correction lens 32. Consequently, the secondary electrons which have passed through the focus correction lens 32 move to the positioning deflector 28 without being decelerated, thus stay of secondary electrons between the focus correction lens 32 and the positioning deflector 28 can be prevented, and the beam irradiation position accuracy can be improved.

In the embodiment, the configuration in which a multi-beam is used has been described. However, the configuration in which a single beam is used may be adopted.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A charged particle beam writing method comprising:
deflecting a charged particle beam at a position with a deflection offset added so that a zero-state of any deflection voltage is excluded from a range of deflection voltages applied to a plurality of electrodes of an electrostatic positioning deflector;
irradiating a substrate with the charged particle beam; and
changing a quadrant of the deflection offset at a predetermined timing or based on a drift amount of the charged particle beam, the quadrant being relative to an origin of deflection voltage at which all deflection voltages are zero.

2. The charged particle beam writing method according to claim 1,
wherein the charged particle beam is deflected to the position with the deflection offset added so that a polarity of a voltage of each of the electrodes does not vary in the range of deflection voltages.

3. The charged particle beam writing method according to claim 1,
wherein a drift amount of the charged particle beam is measured, and when the drift amount is greater than or equal to a threshold value, the quadrant of the deflection offset is changed.

4. The charged particle beam writing method according to claim 3,
wherein when the drift amount is greater than or equal to a threshold value, the quadrant and size of the deflection offset are changed.

5. The charged particle beam writing method according to claim 3,
wherein a change destination of the quadrant of the deflection offset is selected at random.

6. The charged particle beam writing method according to claim 3,
wherein change of the quadrant of the deflection offset and measurement of the drift amount are made for multiple times, and a quadrant in which the drift amount is minimum is selected as a change destination.

7. The charged particle beam writing method according to claim 1,
wherein a focus correction lens disposed downstream of the positioning deflector in a traveling direction of the multi-charged particle beam is operated in a positive voltage range.

8. The charged particle beam writing method according to claim 7,
wherein a common voltage is added to a voltage to be applied to each of the plurality of electrodes of the positioning deflector, the common voltage being higher than or equal to an upper limit value of a voltage applied to the focus correction lens.

9. A charged particle beam writing apparatus comprising:
an electrostatic positioning deflector that has a plurality of electrodes, and deflects a charged particle beam to be emitted to a substrate as a writing target; and
a deflection control circuit that performs deflection control on the charged particle beam to a position with a deflection offset added so that a zero-state of any deflection voltage is excluded from a range of deflection voltages applied to the plurality of electrodes, and changes a quadrant of the deflection offset at a predetermined timing or based on a drift amount of the charged particle beam, the quadrant being relative to an origin of deflection voltage at which all deflection voltages are zero.

10. The charged particle beam writing apparatus according to claim 9,
wherein the deflection control circuit deflects the charged particle beam to the position with the deflection offset added so that a polarity of a voltage of each of the electrodes does not vary in the range of deflection voltages.

11. The charged particle beam writing apparatus according to claim 9,
wherein the deflection control circuit measures a drift amount of the charged particle beam, and changes the quadrant of the deflection offset when the drift amount is greater than or equal to a threshold value.

12. The charged particle beam writing apparatus according to claim 11,
wherein the deflection control circuit changes the quadrant and size of the deflection offset when the drift amount is greater than or equal to a threshold value.

13. The charged particle beam writing apparatus according to claim 11,
wherein the deflection control circuit selects a change destination of the quadrant of the deflection offset at random.

14. The charged particle beam writing apparatus according to claim 11,
wherein the deflection control circuit changes the quadrant of the deflection offset and measures the drift amount for multiple times, and selects a quadrant in which the drift amount is minimum as a change destination.

15. The charged particle beam writing apparatus according to claim 9,
wherein the deflection control circuit operates a focus correction lens disposed downstream of the positioning deflector in a traveling direction of the multi-charged particle beam in a positive voltage range.

16. The charged particle beam writing apparatus according to claim 15,
wherein the deflection control circuit adds a common voltage to a voltage to be applied to each of the plurality of electrodes of the positioning deflector, the common voltage being higher than or equal to an upper limit value of a voltage applied to the focus correction lens.
